(19) United States
(12) Patent Application Publication
(10) Pub. No.: US 2023/0115455 A1
(43) Pub. Date: Apr. 13, 2023

(54) SEMICONDUCTOR SENSOR

(71) Applicant: Murata Manufacturing Co., Ltd., Nagaokakyo-shi (JP)

(72) Inventors: Naruto MIYAKAWA, Nagaokakyo-shi (JP); Shota USHIBA, Nagaokakyo-shi (JP); Ayumi SHINAGAWA, Nagaokakyo-shi (JP); Yuka OKA, Nagaokakyo-shi (JP); Masahiko KIMURA, Nagaokakyo-shi (JP)

(21) Appl. No.: 18/079,927

(22) Filed: Dec. 13, 2022

Related U.S. Application Data
(63) Continuation of application No. PCT/JP2021/022087, filed on Jun. 10, 2021.

(30) Foreign Application Priority Data
Jul. 3, 2020 (JP) 2020-115914

(51) Int. Cl. H01L 23/498; H01L 23/14

(52) U.S. Cl. CPC H01L 23/49822; H01L 23/49861; H01L 23/142

(57) ABSTRACT

A semiconductor sensor includes a substrate, a dielectric layer on the substrate, a first electrode on the dielectric layer, and a second electrode spaced apart from the first electrode and on the dielectric layer, a semiconductor sheet between the first electrode and the second electrode on the dielectric layer and electrically connecting the first electrode and the second electrode to each other, a third electrode at least a portion of which is covered by the dielectric layer and faces the semiconductor sheet with the dielectric layer interposed therebetween, and multiple first attraction portions at least on a surface of the third electrode or in or on the dielectric layer on the surface of the third electrode and attracting an object to be detected.

### CROSS REFERENCE TO RELATED APPLICATIONS

This application claims the benefit of priority to Japanese Patent Application No. 2020-115914 filed on Jul. 3, 2020 and is a Continuation Application of PCT Application No. PCT/JP2021/022087 filed on Jun. 10, 2021. The entire contents of each application are hereby incorporated herein by reference.

### BACKGROUND OF THE INVENTION

### 1. Field of the Invention

The present invention relates to a semiconductor sensor.

### 2. Description of the Related Art

International Publication No. 2016/021693 discloses a field-effect transistor and a sensor that uses the field-effect transistor. The field-effect transistor disclosed in International Publication No. 2016/021693 uses non-metal material particles as growth nuclei, and the channel of the field-effect transistor is composed of carbon nanotube thin film that is grown by a chemical vapor deposition method.

In recent years, there has been a need to improve the performance of a semiconductor sensor.

### SUMMARY OF THE INVENTION

Preferred embodiments of the present invention provide semiconductor sensors that each have improved performance.

A semiconductor sensor according to a preferred embodiment of the present invention includes a substrate, a dielectric layer on the substrate, a first electrode on the dielectric layer, and a second electrode spaced apart from the first electrode and on the dielectric layer, a semiconductor sheet between the first electrode and the second electrode on the dielectric layer and electrically connecting the first electrode and the second electrode to each other, a third electrode at least a portion of which is covered by the dielectric layer and faces the semiconductor sheet with the dielectric layer interposed therebetween, and multiple first attraction portions at least on a surface of the third electrode or in or on the dielectric layer on the surface of the third electrode and attracting an object to be detected.

According to preferred embodiments of the present invention, semiconductor sensors that each have improved performance are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A schematically illustrates a perspective view of an example of a main structure of a semiconductor sensor according to a first preferred embodiment of the present invention.

FIG. 1B schematically illustrates a perspective view of an example of a main structure of a detection device according to the first preferred embodiment of the present invention.

FIG. 2 schematically illustrates a plan view of an example of the main structure of the semiconductor sensor according to the first preferred embodiment of the present invention.

FIG. 3A schematically illustrates a sectional view of the semiconductor sensor in FIG. 2 taken along line A-A.

FIG. 3B schematically illustrates a sectional view of the detection device according to the first preferred embodiment of the present invention.

FIG. 4A schematically illustrates a sectional view of an example of the structure of a portion Z1 of the detection device in FIG. 3B.

FIG. 4B schematically illustrates a sectional view of an example of the structure of a portion Z2 of the detection device in FIG. 3B.

FIG. 5 schematically illustrates an example of a detection device that includes a calculator according to a preferred embodiment of the present invention.

FIG. 6A schematically illustrates an example in which an object to be detected is attracted in a semiconductor sensor according to a preferred embodiment of the present invention.

FIG. 6B schematically illustrates an example of a variation in electric current in a case where the object to be detected is attracted.

FIG. 7A schematically illustrates a sectional view of an example of a main structure of a semiconductor sensor according to a first modification to the first preferred embodiment of the present invention.

FIG. 7B schematically illustrates a sectional view of an example of a main structure of a detection device according to the first modification to the first preferred embodiment of the present invention.

FIG. 7C schematically illustrates a sectional view of an example of the structure of a portion Z3 of the detection device in FIG. 7B.

FIG. 8 schematically illustrates a sectional view of an example of a main structure of a detection device according to a second modification to the first preferred embodiment of the present invention.

FIG. 9A schematically illustrates an example of a structure for capacitive coupling.

FIG. 9B schematically illustrates an example of a structure for capacitive coupling.

FIG. 9C schematically illustrates an example of a structure for capacitive coupling.

FIG. 10A schematically illustrates a sectional view of an example of a main structure of a semiconductor sensor according to a second preferred embodiment of the present invention.

FIG. 10B schematically illustrates a sectional view of an example of a main structure of a detection device according to the second preferred embodiment of the present invention.

FIG. 11A schematically illustrates a sectional view of an example of a main structure of a semiconductor sensor according to a third preferred embodiment of the present invention.

FIG. 11B schematically illustrates a sectional view of an example of a main structure of a detection device according to the third preferred embodiment of the present invention.

FIG. 12A schematically illustrates a sectional view of an example of a main structure of a semiconductor sensor according to a fourth preferred embodiment of the present invention.

FIG. 12B schematically illustrates a sectional view of an example of a main structure of a detection device according to the fourth preferred embodiment of the present invention.

FIG. 13A schematically illustrates a sectional view of an example of a main structure of a semiconductor sensor according to a fifth preferred embodiment of the present invention.

FIG. 13B schematically illustrates a sectional view of an example of a main structure of a detection device according to the fifth preferred embodiment of the present invention.

FIG. 14A schematically illustrates a sectional view of a main structure of a detection device according to a third modification to the fifth preferred embodiment of the present invention.

FIG. 14B schematically illustrates a sectional view of a main structure of a detection device according to a fourth modification to the fifth preferred embodiment of the present invention.

FIG. 15 schematically illustrates a sectional view of an example of a main structure of a detection device according to a sixth preferred embodiment of the present invention.

FIG. 16 schematically illustrates an example of the variation in the electric current in the case where multiple objects to be detected are attracted.

FIG. 17 schematically illustrates an example of a dynamic range.

FIG. 18 schematically illustrates a sectional view of a main structure of a detection device according to a fifth modification to the sixth preferred embodiment of the present invention.

### DETAILED DESCRIPTION OF THE PREFERRED EMBODIMENTS

A solution top-gate FET that is used for, for example, a biosensor is known as a semiconductor sensor. In the semiconductor sensor, for example, a semiconductor channel is formed by using a semiconductor sheet such as graphene that is electrically connected to a drain electrode and a source electrode.

For a sensor that uses a semiconductor sheet, for example, a receptor that combines a specific target molecule and a surface of the semiconductor sheet is provided. When the target molecule and the receptor are specifically combined, the electrical characteristics of the semiconductor sheet are modulated due to the electric charge of the target molecule. The semiconductor sensor senses the presence or absence of the target molecule by measuring the modulation of the electrical characteristics of the semiconductor sheet.

The inventors of preferred embodiments of the present invention have researched and discovered that the gate drive of a semiconductor sensor that includes a semiconductor sheet can occur not only from a front surface of the semiconductor sheet that is a two-dimensional semiconductor but also from a back surface. Specifically, the inventors of preferred embodiments of the present invention have developed the structure of the semiconductor sensor that includes a back gate electrode that faces the semiconductor sheet and an electrolyte solution with a dielectric layer interposed therebetween and multiple attraction portions that are disposed at least on a surface of the back gate electrode or in or on the dielectric layer that is disposed on the surface of the back gate electrode. The inventors of preferred embodiments of the present invention have discovered that this enables the performance of the semiconductor sensor to be improved. Preferred embodiments of the present invention will be described based on this.

A semiconductor sensor according to a preferred embodiment of the present invention includes a substrate, a dielectric layer that is disposed on the substrate, a first electrode that is disposed on the dielectric layer, and a second electrode that is spaced apart from the first electrode and that is disposed on the dielectric layer, a semiconductor sheet that is disposed between the first electrode and the second electrode on the dielectric layer and that electrically connects the first electrode and the second electrode to each other, a third electrode at least a portion of which is covered by the dielectric layer and that faces the semiconductor sheet with the dielectric layer interposed therebetween, and multiple first attraction portions that are disposed at least on a surface of the third electrode or in or on the dielectric layer disposed on the surface of the third electrode and that attract an object to be detected.

With this structure, the performance of the semiconductor sensor can be improved.

The semiconductor sensor may further include a cover layer that is disposed on the dielectric layer and that covers the first electrode, the second electrode, and the semiconductor sheet.

With this structure, the cover layer can protect the first electrode, the second electrode, and the semiconductor sheet.

The semiconductor sensor may further include multiple second attraction portions that are disposed on the semiconductor sheet and that attract an object to be detected.

With this structure, the performance of the semiconductor sensor can be further improved.

The multiple second attraction portions may attract a second object to be detected different from a first object to be detected that the multiple first attraction portions attract.

With this structure, the two objects to be detected can be detected.

The dielectric layer may be a first dielectric layer that covers at least a portion of the third electrode on the substrate, and the semiconductor sensor may further include a second dielectric layer that is disposed on the first dielectric layer and that covers the first electrode, the second electrode, and the semiconductor sheet, a fourth electrode that is disposed on the second dielectric layer, and multiple third attraction portions that are disposed on the fourth electrode and that attract an object to be detected.

With this structure, the performance of the semiconductor sensor can be further improved.

The fourth electrode may include a second body electrode that is disposed on the second dielectric layer, a second outer electrode that is spaced apart from the second body electrode, and a second connection line that connects the second body electrode and the second outer electrode to each other, and the multiple third attraction portions that attract the object to be detected may be disposed on a surface of the second outer electrode.

With this structure, the performance of the semiconductor sensor can be further improved.

The multiple third attraction portions may attract a third object to be detected different from a first object to be detected that the multiple first attraction portions attract.

With this structure, the two objects to be detected can be detected.

The dielectric layer may be a first dielectric layer that covers at least a portion of the third electrode on the substrate. The semiconductor sensor may further include a second dielectric layer that is disposed on the first dielectric layer and that covers the first electrode, the second electrode, and the semiconductor sheet, a fourth electrode that is disposed on the second dielectric layer, and a connection conductor that connects the third electrode and the fourth electrode to each other, the third electrode may include a first body electrode that is covered by the first dielectric layer, a first outer electrode that is spaced apart from the first body electrode, and a first connection line that connects the first body electrode and the first outer electrode to each other, and the multiple first attraction portions may be disposed on a surface of the first outer electrode.

With this structure, the performance of the semiconductor sensor can be further improved.

The third electrode may define and function as the substrate.

With this structure, the number of components can be decreased.

The semiconductor sensor may further include a calculator that receives an electrical signal outputted from the semiconductor sheet and that calculates an amount of the object to be detected, based on the electrical signal.

With this structure, the amount of the object to be detected can be calculated.

A detection device according to a preferred embodiment of the present invention includes the semiconductor sensor according to a preferred embodiment of the present invention, and a fifth electrode that controls an electric current between the first electrode and the second electrode.

With this structure, the performance of the detection device can be improved.

Preferred embodiments of the present invention will now be described with reference to the accompanying drawings. In the drawings, components may be exaggeratedly illustrated to make the description easy to understand.

### First Preferred Embodiment

Overall Structure

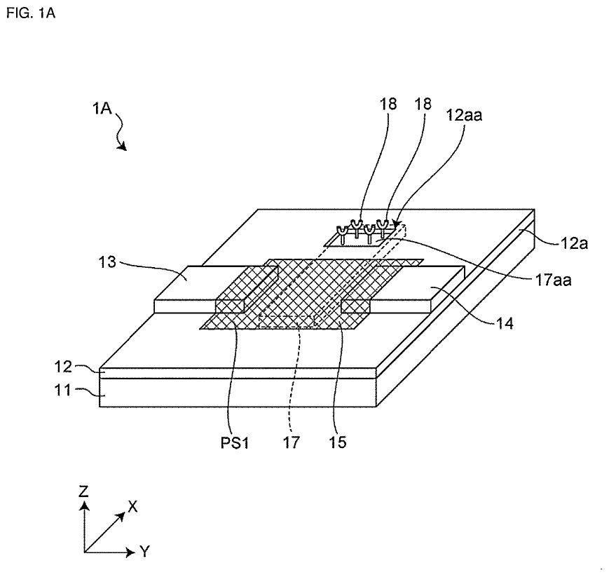

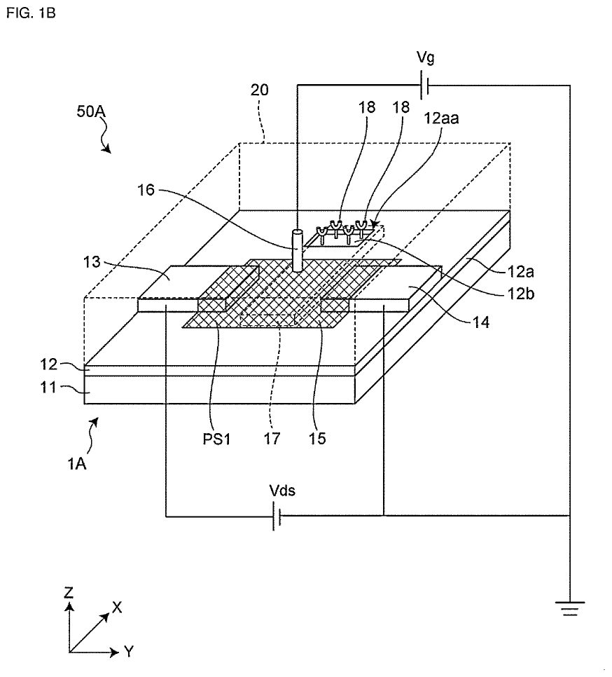

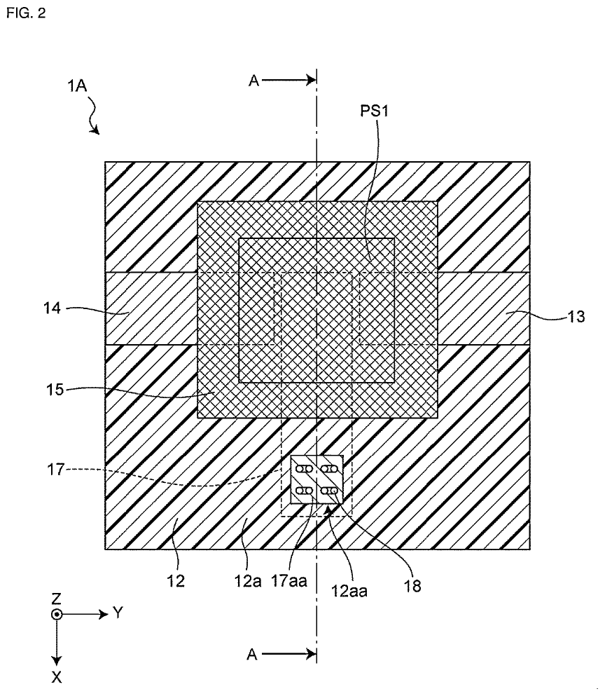

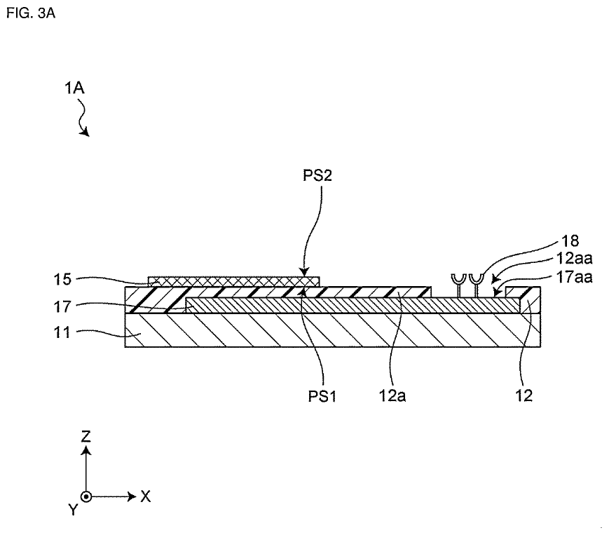

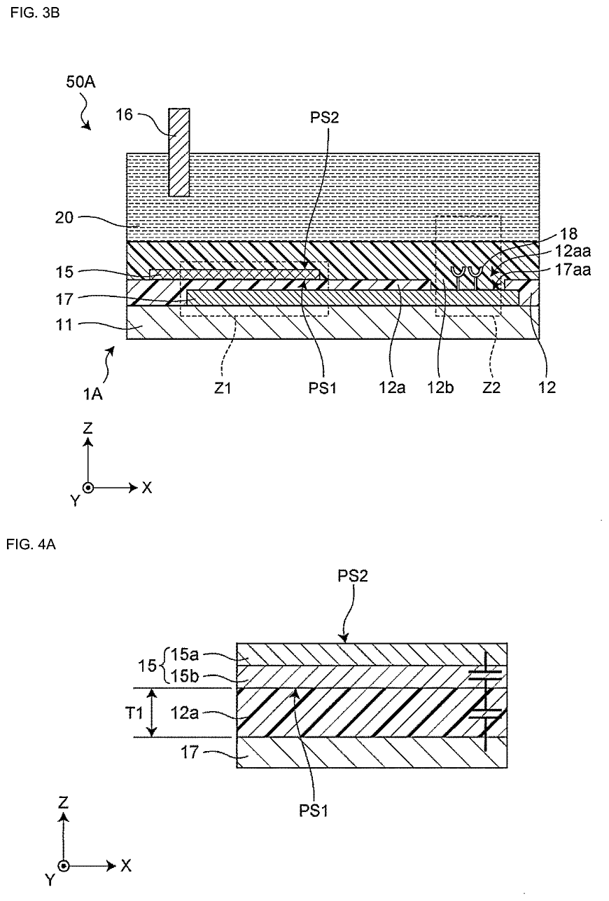

FIG. 1A schematically illustrates a perspective view of an example of a main structure of a semiconductor sensor 1A according to a first preferred embodiment of the present invention. FIG. 1B schematically illustrates a perspective view of an example of a main structure of a detection device 50A according to the first preferred embodiment of the present invention. FIG. 2 schematically illustrates a plan view of an example of the main structure of the semiconductor sensor 1A according to the first preferred embodiment of the present invention. FIG. 3A schematically illustrates a sectional view of the semiconductor sensor 1A in FIG. 2 taken along line A-A. FIG. 3B schematically illustrates a sectional view of the detection device 50A according to the first preferred embodiment of the present invention. An X-direction, a Y-direction, and a Z-direction in the figures respectively represent the longitudinal direction, the transverse direction, and the height direction of the semiconductor sensor 1A.

As illustrated in FIG. 1A to FIG. 3B, the semiconductor sensor 1A includes a substrate 11, a dielectric layer 12, a first electrode 13, a second electrode 14, a semiconductor sheet 15, a third electrode 17, and multiple attraction portions 18. In the semiconductor sensor 1A, the first electrode 13, the second electrode 14, and the third electrode 17 are respectively referred to as a drain electrode, a source electrode, and a back gate electrode in some cases.

The detection device 50A includes the semiconductor sensor 1A and an additional electrode 16. In the detection device 50A, the semiconductor sensor 1A is filled with an electrolyte solution 20. Examples of the electrolyte solution 20 include phosphate-buffered saline, a sodium chloride solution, a potassium chloride solution, a calcium chloride solution, a sodium hydrogen carbonate solution, a potassium carbonate solution, a phosphate buffer solution, an acetate buffer solution, a tris buffer solution, a MES buffer solution, and a mixed solution that partially includes these.

In the detection device 50A, a drain-source voltage Vds is applied between the first electrode 13 and the second electrode 14. In some cases, the additional electrode 16 is referred to as the fifth electrode 16 or a gate electrode. The additional electrode 16 is connected to an external power supply and applies a gate voltage Vg.

Semiconductor Sensor

The detailed structure of the semiconductor sensor 1A will be described.

Substrate

The substrate 11 has a plate shape. The third electrode 17 and the dielectric layer 12 are disposed on the substrate 11. According to the first preferred embodiment, the substrate 11 is made of, for example, an insulating material. The substrate 11 is made of, for example, an insulating material such as SiO₂.

Dielectric Layer

The dielectric layer 12 is disposed on the substrate 11. The dielectric layer 12 covers the third electrode 17 on the substrate 11. The dielectric layer 12 is made of a dielectric material that has a plate shape. According to the first preferred embodiment, the dielectric layer 12 includes an insulating layer 12a.

The insulating layer 12a is disposed on the substrate 11 and covers a surface of the third electrode 17. The insulating layer 12a is made of an insulating material. Examples of the insulating material include ceramics such as SiO₂, Si₃N₄, Al₂O₃, and HfO₂, a resin material such as epoxy resin, polyimide resin, silicone resin, fluorine resin, and photoresist, and a two-dimensional insulating material such as boron nitride. According to the first preferred embodiment, the insulating layer 12a includes an opening 12aa through which a surface 17aa of the third electrode 17 is exposed. The surface 17aa of the third electrode 17 is opposite a surface in contact with the substrate 11.

As illustrated in FIG. 1B and FIG. 3B, an electric double layer 12b is provided on the insulating layer 12a and the surface 17aa of the third electrode 17 that is exposed through the opening 12aa of the insulating layer 12a with the semiconductor sensor 1A filled with the electrolyte solution 20. The electric double layer 12b corresponds to a dielectric provided at the interface between the third electrode 17 and the electrolyte solution 20 and the interface between the insulating layer 12a and the electrolyte solution. The electric double layer 12b is, for example, a liquid layer.

According to the first preferred embodiment, it is not necessary for the electric double layer 12b to be provided on the insulating layer 12a.

The thickness of the insulating layer 12a is designed to be a dimension adjusted to such an extent that capacitive coupling between the semiconductor sheet 15 and the third electrode 17 occurs. The electric double layer 12b has a thickness adjusted to such an extent that capacitive coupling between the electrolyte solution 20 and the third electrode 17 occurs. The capacitive coupling will be described in detail later.

First Electrode

The first electrode 13 is disposed on the dielectric layer 12. Specifically, the first electrode 13 is disposed on the insulating layer 12a. The first electrode 13 has a plate shape. The first electrode 13 has a rectangular or substantially rectangular shape that extends in the Y-direction in a plan view of the semiconductor sensor 1A. The first electrode 13 is made of a conductive material. For example, the first electrode 13 is composed of a conductive material such as Cu, Ti, Ni, Cr, Au, or Pt. According to the first preferred embodiment, the first electrode 13 defines and functions as the drain electrode.

Second Electrode

The second electrode 14 is spaced apart from the first electrode 13 and is disposed on the dielectric layer 12. Specifically, the second electrode 14 faces the first electrode 13 on the insulating layer 12a. The second electrode 14 has a plate shape. The second electrode 14 has a rectangular or substantially rectangular shape that extends in the Y-direction in a plan view of the semiconductor sensor 1A. The second electrode 14 is made of the same conductive material as the first electrode 13. According to the first preferred embodiment, the second electrode 14 defines and functions as the source electrode.

Semiconductor Sheet

The semiconductor sheet 15 is made of a semiconductor. The semiconductor sheet 15 is made of a conductive material and outputs an electrical signal (for example, an electric current signal) converted based on attachment of an object to be detected. The electrical characteristics (for example, current-voltage characteristics) of the semiconductor sheet 15 change when the object to be detected is attached. For example, the semiconductor sheet 15 is made of, for example, graphene, a carbon nanotube, an organic semiconductor, MXENES and a transition-metal dichalcogenide layer material, a silicon thin film, or a silicon nanowire. According to the first preferred embodiment, the semiconductor sheet 15 is made of graphene, for example. The graphene has carrier mobility higher than those of other semiconductor materials. As a result, the amount of an electric current that is modulated due to the attachment of the same object to be detected can be larger than those of the other semiconductor materials.

The thickness of the semiconductor sheet 15 is, for example, no less than about 0.3 nm and no more than about 300 nm.

The semiconductor sheet 15 is disposed between the first electrode 13 and the second electrode 14 on the dielectric layer 12 and electrically connects the first electrode 13 and the second electrode 14 to each other. Specifically, the semiconductor sheet 15 is disposed across the first electrode 13 and the second electrode 14 on the insulating layer 12a. The semiconductor sheet 15 is disposed on a portion of a surface of the first electrode 13, the insulating layer 12a between the first electrode 13 and the second electrode 14, and a portion of a surface of the second electrode 14. In this way, the semiconductor sheet 15 can be used as a semiconductor channel.

The semiconductor sheet 15 includes a first main surface PS1 and a second main surface PS2 opposite the first main surface PS1. According to the first preferred embodiment, the first main surface PS1 corresponds to a back surface of the semiconductor sheet 15 and is in contact with the insulating layer 12a of the dielectric layer 12. The second main surface PS2 corresponds to a front surface of the semiconductor sheet 15 and is in contact with the electrolyte solution 20.

The semiconductor sheet 15 is in close contact with the second electrode 14, the first electrode 13, and the insulating layer 12a of the dielectric layer 12 by using van der Waals force.

PMMA (Polymethyl methacrylate) that, for example, defines and functions as a protection film may be applied to the front surface of the semiconductor sheet 15.

Third Electrode

The third electrode 17 has a plate shape that includes a first end and a second end and that extends in the longitudinal direction. The third electrode 17 has a rectangular or substantially rectangular shape that extends in the X-direction in a plan view of the semiconductor sensor 1A. The third electrode 17 is made of a conductive material such as, for example, Cu, Ti, Ni, Cr, Au, or Pt.

The third electrode 17 is disposed on the substrate 11. The third electrode 17 faces the first main surface PS1 of the semiconductor sheet 15. As illustrated in FIG. 2, the third electrode 17 is disposed between the first electrode 13 and the second electrode 14 in a plan view of the semiconductor sensor 1A. Specifically, the first end of the third electrode 17 is disposed between the first electrode 13 and the second electrode 14. The third electrode 17 may partly overlap the first electrode 13 and the second electrode 14 in a plan view of the semiconductor sensor 1A.

At least a portion of the third electrode 17 is covered by the dielectric layer 12. According to the first preferred embodiment, a portion of the surface of the third electrode 17 is exposed through the opening 12aa of the insulating layer 12a of the dielectric layer 12. Specifically, the surface 17aa of the third electrode 17 at the second end is exposed through the opening 12aa of the insulating layer 12a.

As illustrated in FIG. 3A and FIG. 3B, the third electrode 17 faces the semiconductor sheet 15 with the dielectric layer 12 interposed therebetween. Specifically, the first end of the third electrode 17 faces the semiconductor sheet 15 with the insulating layer 12a interposed therebetween. The surface opposite the surface in contact with the substrate 11 at the first end of the third electrode 17 faces the first main surface PS1 of the semiconductor sheet 15 with the insulating layer 12a interposed therebetween.

The surface 17aa of the third electrode 17 at the second end of the third electrode 17 is exposed through the opening 12aa of the insulating layer 12a. The electric double layer 12b is provided on the surface 17aa of the third electrode 17 with the semiconductor sensor 1A filled with the electrolyte solution 20. The second end of the third electrode 17 faces the electrolyte solution 20 with the electric double layer 12b interposed therebetween. Before the electrolyte solution 20 is filled, the surface 17aa of the third electrode 17 at the second end of the third electrode 17 is thus exposed through the opening 12aa of the insulating layer 12a. After the electrolyte solution 20 is filled, the surface 17aa of the third electrode 17 at the second end of the third electrode 17 faces the electrolyte solution 20 with the electric double layer 12b interposed therebetween.

The capacitive coupling of the third electrode 17 with the semiconductor sheet 15 and the electrolyte solution 20 occurs. Specifically, the capacitive coupling between the third electrode 17 and the semiconductor sheet 15 occurs at a portion that faces the semiconductor sheet 15, that is, a portion Z1 illustrated in FIG. 3B with the insulating layer 12a interposed therebetween. The capacitive coupling between the third electrode 17 and the electrolyte solution 20 occurs at a portion that faces the electrolyte solution 20, that is, a portion Z2 illustrated in FIG. 3B with the electric double layer 12b interposed therebetween. Consequently, the third electrode 17 functions as the back gate electrode in an electrically floating state. The “electrically floating state” means a state in which there is no connection to the external power supply, and the electric potential is not fixed unlike the gate electrode.

A condition in which the capacitive coupling of the third electrode 17 with the semiconductor sheet 15 and the electrolyte solution 20 occurs is that the thickness of the dielectric of which the insulating layer 12a and/or the electric double layer 12b is composed, and the third electrode 17 is no less than about 0.3 nm and no more than about 100 nm, for example. The thickness of the dielectric is preferably, for example, no less than about 1 nm and no more than about 50 nm. The thickness of the dielectric is more preferably, for example, no less than about 2 nm and no more than about 20 nm.

FIG. 4A schematically illustrates a sectional view of an example of the structure of the portion Z1 of the semiconductor sensor 1A in FIG. 3B. As illustrated in FIG. 4A, the third electrode 17, the insulating layer 12a, and the semiconductor sheet 15 are arranged in this order at the portion Z1. That is, the insulating layer 12a is disposed between the third electrode 17 and the semiconductor sheet 15. The semiconductor sheet 15 includes a semiconductor 15a and a carrier modulation region 15b. A condition in which the capacitive coupling between the semiconductor sheet 15 and the third electrode 17 occurs at the portion Z1 is that the thickness T1 of the insulating layer 12a is no less than about 0.3 nm and no more than about 100 nm, for example. The thickness T1 of the insulating layer 12a is preferably, for example, no less than about 1 nm and no more than about 50 nm. The thickness T1 of the insulating layer 12a is more preferably, for example, no less than about 2 nm and no more than about 20 nm. The thickness T1 of the insulating layer 12a means the thickness of a portion of the insulating layer 12a that is put between the semiconductor sheet 15 and the third electrode 17.

FIG. 4B schematically illustrates a sectional view of an example of the structure of the portion Z2 of the semiconductor sensor 1A in FIG. 3B. As illustrated in FIG. 4B, the third electrode 17, the electric double layer 12b, and the electrolyte solution 20 are arranged in this order at the portion Z2. That is, the electric double layer 12b is disposed between the third electrode 17 and the electrolyte solution 20. A condition in which the capacitive coupling between the third electrode 17 and the electrolyte solution 20 occurs at the portion Z2 is that the thickness T2 of the electric double layer 12b is no less than about 0.3 nm and no more than about 30 nm, for example. The thickness T2 of the electric double layer 12b is preferably, for example, no less than about 1 nm and no more than about 20 nm. The thickness T2 of the electric double layer 12b is more preferably, for example, no less than about 2 nm and no more than about 10 nm.

Multiple Attraction Portions

The multiple attraction portions 18 attract the object to be detected. Examples of the object to be detected include target molecules such as viruses. Examples of the multiple attraction portions 18 include receptors that attract the target molecules. In the present specification, the multiple attraction portions 18 are referred to as the multiple first attraction portions 18 in some cases.

As illustrated in FIG. 3A, the multiple attraction portions 18 are disposed on the surface 17aa of the third electrode 17. Specifically, the multiple attraction portions 18 are disposed on the surface 17aa of the third electrode 17 that is exposed through the opening 12aa of the insulating layer 12a.

As illustrated in FIG. 3B, the electric double layer 12b is provided on the surface 17aa of the third electrode 17 with the electrolyte solution 20 filled. Consequently, the multiple attraction portions 18 are disposed in the electric double layer 12b. The capacitive coupling between the third electrode 17 and the electrolyte solution 20 occurs with the electric double layer 12b interposed therebetween. The multiple attraction portions 18 are disposed in or on a portion at which the capacitive coupling between the third electrode 17 and the electrolyte solution 20 occurs. The multiple attraction portions 18 are disposed in the electrolyte solution 20 and attract the target molecules (the object to be detected) in the electrolyte solution 20.

The capacitive coupling of the third electrode 17 with the semiconductor sheet 15 and the electrolyte solution 20 occurs. For this reason, when the multiple attraction portions 18 that are disposed in or on the portion at which the capacitive coupling between the third electrode 17 and the electrolyte solution 20 occurs attract the target molecules, the electrical characteristics of the semiconductor sheet 15 change due to the electric charge of the target molecules. Accordingly, the object to be detected can be detected by detecting changes in the electrical characteristics of the semiconductor sheet 15.

Detection Device

The detailed structure of the detection device 50A will be described.

The detection device 50A includes the semiconductor sensor 1A described above and the additional electrode 16 that controls the electric current between the first electrode 13 and the second electrode 14.

Additional Electrode

The additional electrode 16 controls the electric potential of the electrolyte solution 20. The additional electrode 16 is in contact with the electrolyte solution 20 and controls the electric current between the first electrode 13 and the second electrode 14. The additional electrode 16 has a columnar shape. The additional electrode 16 is a reference electrode made of, for example, Ag/AgCl. The additional electrode 16 may be made of single metal that is stable in a solution such as, for example, Au or Pt instead. According to the first preferred embodiment, the additional electrode 16 defines and functions as the gate electrode.

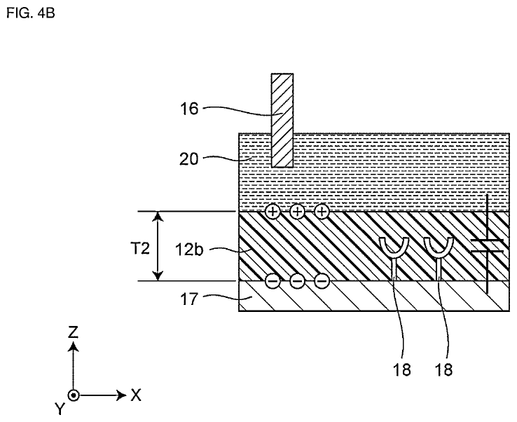

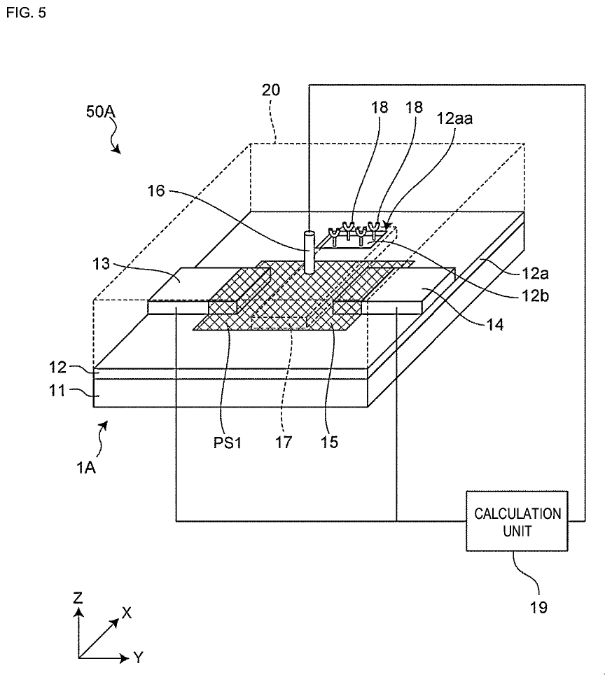

FIG. 5 schematically illustrates an example of the detection device 50A that includes a calculator 19. As illustrated in FIG. 5, the calculator 19 is connected to the first electrode 13, the second electrode 14, and the additional electrode 16. The calculator 19 receives the electrical signal that is outputted from the semiconductor sheet 15 and calculates the amount of the object to be detected, based on the electrical signal. The calculator 19 quantitatively detects the object to be detected, based on the electrical signal. According to the first preferred embodiment, the calculator 19 is included in the semiconductor sensor 1A. The calculator 19 may be included in the detection device 50A, whereas the calculator 19 is not included in the semiconductor sensor 1A.

It is known that the amount of a variation in the electrical signal that is outputted from the semiconductor sheet 15 and the amount of the object to be detected have a correlation. The calculator 19 calculates the amount of the object to be detected, based on the amount of the variation in the electrical signal. Consequently, the presence or absence of the object to be detected can be determined, and/or concentration can be calculated.

The calculator 19 controls the drain-source voltage Vds that is applied between the first electrode 13 and the second electrode 14 and the gate voltage Vg that is applied to the fifth electrode 16.

The calculator 19 can be provided by using a semiconductor element. For example, the calculator 19 can include, for example, a microcomputer, a CPU, a MPU, a GPU, a DSP, a FPGA, an ASIC, a discrete semiconductor, or a LSI. The function of the calculator 19 may be performed by using only hardware or may be performed by using a combination of hardware and software. The calculator 19 reads a program and data that are stored in a storage, not illustrated, in the calculator 19, performs various kinds of calculation processing, and consequently fulfils the predetermined function. Examples of the storage can include a hard disk (HDD), a SSD, a RAM, a DRAM, a ferroelectric random access memory, a flash memory, a magnetic disk, and a combination thereof.

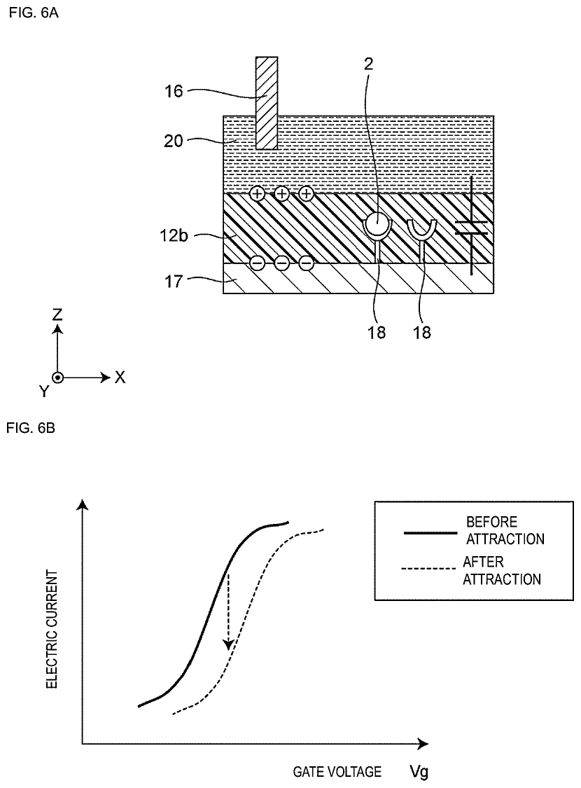

FIG. 6A schematically illustrates an example in which an object 2 to be detected is attracted in the semiconductor sensor 1A. FIG. 6B schematically illustrates an example of the variation in the electric current in the case where the object 2 to be detected is attracted. When the object 2 to be detected is attracted by the attraction portions 18 as illustrated in FIG. 6A, the electrical characteristics of the semiconductor sheet 15 change as illustrated in FIG. 6B. Specifically, the value of the electric current decreases due to the attraction of the object 2 to be detected. The calculator 19 can detect the amount and the presence or absence of the object 2 to be detected, based on the variation in the value of the electric current.

### Advantageous Effects

The semiconductor sensor 1A according to the first preferred embodiment can obtain the following advantageous effects.

The semiconductor sensor 1A includes the substrate 11, the dielectric layer 12, the first electrode 13, the second electrode 14, the semiconductor sheet 15, the third electrode 17, and the multiple attraction portions 18. The dielectric layer 12 is disposed on the substrate 11. The first electrode 13 is disposed on the dielectric layer 12. The second electrode 14 is spaced apart from the first electrode 13 and is disposed on the dielectric layer 12. The semiconductor sheet 15 is disposed between the first electrode 13 and the second electrode 14 on the dielectric layer 12 and electrically connects the first electrode 13 and the second electrode 14 to each other. A portion of the third electrode 17 is covered by the dielectric layer 12 and faces the semiconductor sheet 15 with the dielectric layer 12 interposed therebetween. The multiple attraction portions 18 are disposed on the surface 17aa of the third electrode 17 and attract the object 2 to be detected.

With this structure, the performance of the semiconductor sensor 1A can be improved. In the semiconductor sensor 1A, the multiple attraction portions 18 can be disposed in or on a portion other than the semiconductor sheet 15. Specifically, the multiple attraction portions 18 can be disposed in or on the portions at which the capacitive coupling of the third electrode 17 with the semiconductor sheet 15 and the electrolyte solution 20 occurs. For this reason, the positions in or on which the multiple attraction portions 18 are disposed can be readily increased. This enables the sensor sensitivity of the semiconductor sensor 1A to be improved.

In the case where the multiple attraction portions 18 are not disposed in or on the semiconductor sheet 15, the semiconductor sheet 15 can be reduced or prevented from being damaged due to the multiple attraction portions 18. The multiple attraction portions 18 are more readily disposed on the dielectric layer 12 than in the case where the multiple attraction portions 18 are disposed on the semiconductor sheet 15.

The detection device 50A includes the semiconductor sensor 1A and the additional electrode 16. The additional electrode 16 controls the electric current between the first electrode 13 and the second electrode 14.

With this structure, the same or substantially the same advantageous effects as the advantageous effects described for the semiconductor sensor 1A can be obtained. That is, the performance of the detection device 50A can be improved.

In an example described according to the first preferred embodiment, the substrate 11 is made of an insulating material but is not limited thereto. For example, the substrate 11 may be made of a conductive material.

In an example described according to the first preferred embodiment, the dielectric layer 12 is provided by using the insulating layer 12a but is not limited thereto. The dielectric layer 12 is made of a dielectric material. The dielectric layer 12 has the thickness adjusted to such an extent that the capacitive coupling between the semiconductor sheet 15 and the third electrode 17 occurs.

In an example described according to the first preferred embodiment, the insulating layer 12a includes the opening 12aa, and the surface 17aa of the third electrode 17 is exposed through the opening 12aa, but these are not limited thereto. For example, it is not necessary for the insulating layer 12a to include the opening 12aa, and the surface 17aa of the third electrode 17 may be entirely or substantially entirely covered by the insulating layer 12a. In this case, the capacitive coupling between the third electrode 17 and the electrolyte solution 20 may occur with the insulating layer 12a interposed therebetween. The multiple attraction portions 18 may be disposed on the insulating layer 12a.

In an example described according to the first preferred embodiment, the first electrode 13, the second electrode 14, and the third electrode 17 have a rectangular or substantially rectangular shape in a plan view of the semiconductor sensor 1A but are not limited thereto. The first electrode 13, the second electrode 14, and the third electrode 17 may have a freely selected shape.

In an example described according to the first preferred embodiment, capacitive coupling between the first end of the third electrode 17 and the semiconductor sheet 15 occurs, and capacitive coupling between the second end of the third electrode 17 and the electrolyte solution 20 occurs, but these are not limited thereto. For example, capacitive coupling between the center or approximate center of the third electrode 17 and the semiconductor sheet 15 may occur, and capacitive coupling between both ends of the third electrode 17 and the electrolyte solution 20 may occur. Capacitive coupling between the center or approximate center of the third electrode 17 and the electrolyte solution 20 may occur, and capacitive coupling between the first end or the second end of the third electrode 17 and the semiconductor sheet 15 may occur.

In an example described according to the first preferred embodiment, the object 2 to be detected corresponds to the target molecules such as, for example, viruses but is not limited thereto. Examples of the object 2 to be detected may include bacterium, a blood component, a urine component, a swab component, a saliva component, a sweat component, ions and protons (pH) in a liquid, various chemical substances, and gas in the air.

In an example described according to the first preferred embodiment, the attraction portions 18 are the receptors but are not limited thereto. The attraction portions 18 may be changed depending on the object 2 to be detected. For example, in the case where the object 2 to be detected is a chemical substance, the attraction portions 18 may be sensitive membranes. In the case where the object 2 to be detected is pH, the attraction portions 18 may be, for example, Si₃N₄ or Al₂O₃.

In an example described according to the first preferred embodiment, the semiconductor sensor 1A in the detection device 50A is filled with the electrolyte solution 20 but is not limited thereto. The electrolyte solution 20 is not necessarily provided.

In an example described according to the first preferred embodiment, the additional electrode 16 is included in the detection device 50A but is not limited thereto. The additional electrode 16 may be included in the semiconductor sensor 1A.

First Modification

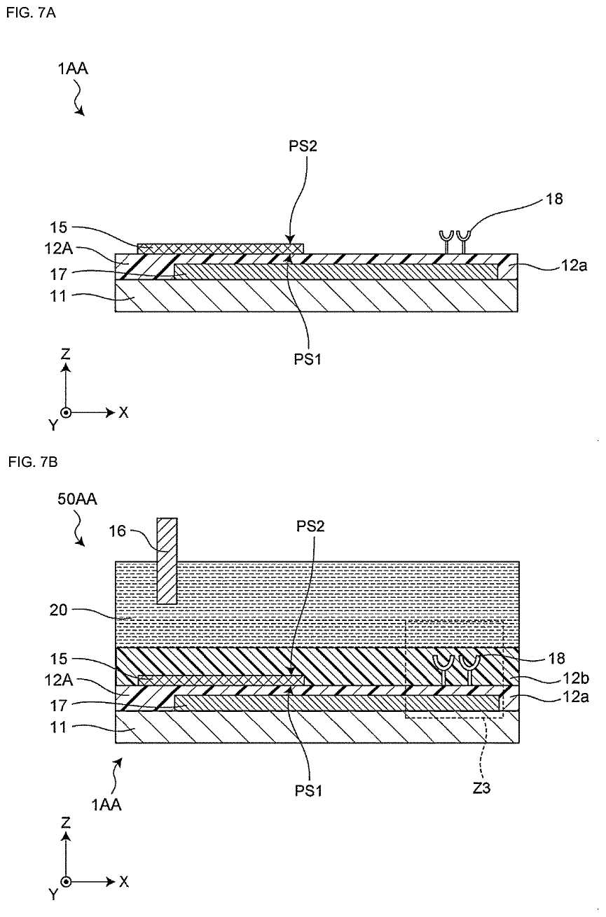

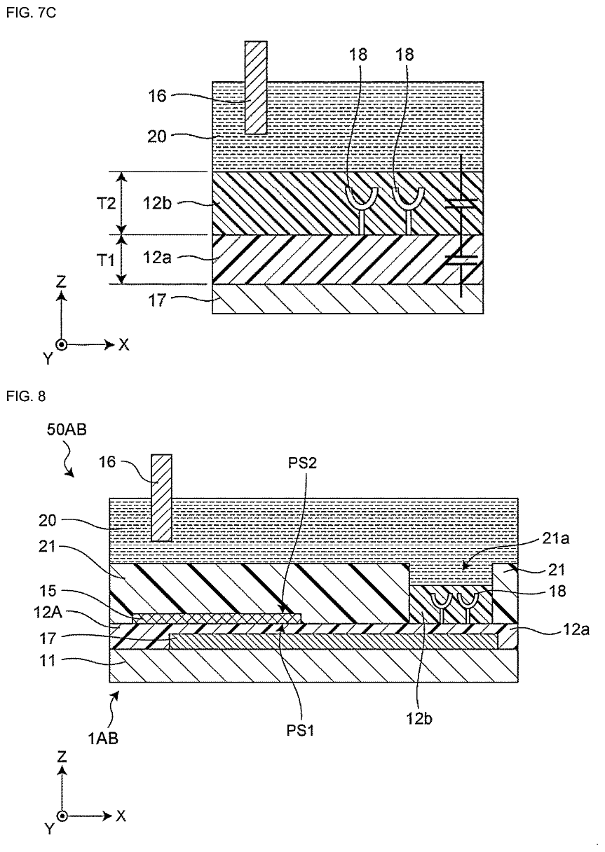

FIG. 7A schematically illustrates a sectional view of an example of a main structure of a semiconductor sensor 1AA according to a first modification to the first preferred embodiment of the present invention. FIG. 7B schematically illustrates a sectional view of an example of a main structure of a detection device 50AA according to the first modification to the first preferred embodiment of the present invention. In FIG. 7B, the semiconductor sensor 1AA is filled with the electrolyte solution 20. As illustrated in FIG. 7A and FIG. 7B, a dielectric layer 12A of the semiconductor sensor 1AA includes an insulating layer 12a that does not include the opening 12aa. That is, in the semiconductor sensor 1AA, the third electrode 17 is covered by the insulating layer 12a and includes no exposed surface. In the semiconductor sensor 1AA, the third electrode 17 faces the electrolyte solution 20 with the insulating layer 12a interposed therebetween. The multiple attraction portions 18 are disposed in or on the insulating layer 12a that is located between the third electrode 17 and the electrolyte solution 20. Specifically, the multiple attraction portions 18 are disposed on a surface of the insulating layer 12a in contact with the electrolyte solution 20.

As illustrated in FIG. 7B, the electric double layer 12b is provided on the surface of the insulating layer 12a of the dielectric layer 12A with the semiconductor sensor 1AA filled with the electrolyte solution 20. The capacitive coupling between the third electrode 17 and the electrolyte solution 20 occurs with the insulating layer 12a and the electric double layer 12b interposed therebetween. The multiple attraction portions 18 are covered by the electric double layer 12b on the insulating layer 12a.

FIG. 7C schematically illustrates a sectional view of an example of the structure of a portion Z3 of the detection device 50AA in FIG. 7B. As illustrated in FIG. 7C, the third electrode 17, the insulating layer 12a, the electric double layer 12b, and the electrolyte solution 20 are arranged in this order at the portion Z3. That is, the insulating layer 12a and the electric double layer 12b are disposed between the third electrode 17 and the electrolyte solution 20. A condition in which the capacitive coupling between the third electrode 17 and the electrolyte solution 20 occurs at the portion Z3 is that the thickness T1 of the insulating layer 12a and the thickness T2 of the electric double layer 12b are respectively equal or substantially equal to the thickness T1 of the insulating layer 12a illustrated in FIG. 4A and the thickness T2 of the electric double layer 12b illustrated in FIG. 4B.

Second Modification

FIG. 8 schematically illustrates a sectional view of an example of a main structure of a detection device 50AB according to a second modification to the first preferred embodiment of the present invention. As illustrated in FIG. 8, a semiconductor sensor 1AB of the detection device 50AB may include a cover layer 21 in addition to the structure of the semiconductor sensor 1AA according to the first modification. The cover layer 21 is disposed on the dielectric layer 12A and covers the first electrode 13, the second electrode 14, and the semiconductor sheet 15. The cover layer 21 is made of, for example, an insulating material. Examples of the insulating material include Si₃N₄ film, TEOS film, epoxy resin, polyimide resin, resist film, and fluorine resin film.

The cover layer 21 includes a hole 21a to provide the portion at which the multiple attraction portions 18 are disposed. The multiple attraction portions 18 are disposed on the dielectric layer 12A in the hole 21a. The electric double layer 12b is provided in the hole 21a with the semiconductor sensor 1AB filled with the electrolyte solution 20. The multiple attraction portions 18 are covered by the electric double layer 12b in the hole 21a.

With this structure, the first electrode 13, the second electrode 14, and the semiconductor sheet 15 can be protected by the cover layer 21. The position of the hole 21a enables the position at which the multiple attraction portions 18 are disposed to be controlled.

The cover layer 21 covers at least a portion of the first electrode 13, the second electrode 14, and the semiconductor sheet 15.

According to the first preferred embodiment, the structure for the capacitive coupling and the portions at which the capacitive coupling occurs are described with reference to examples illustrated in FIG. 4A, FIG. 4B, and FIG. 7C. However, these are not limited thereto. In an example described above, the multiple attraction portions 18 are disposed on the surface 17aa of the third electrode 17 or in or on the insulating layer 12a but are not limited thereto. The multiple attraction portions 18 may be disposed in or on the portions at which the capacitive coupling occurs. For example, the multiple attraction portions 18 may be disposed on the second main surface PS2 of the semiconductor sheet 15.

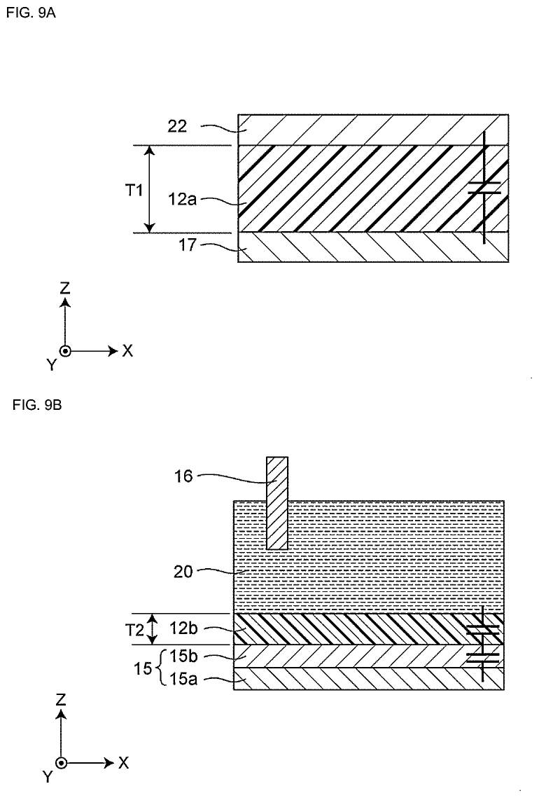

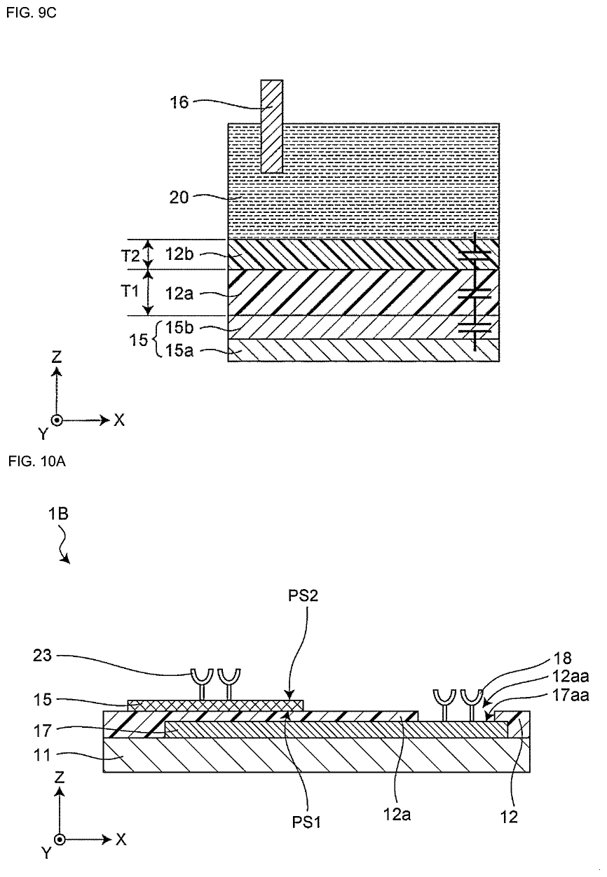

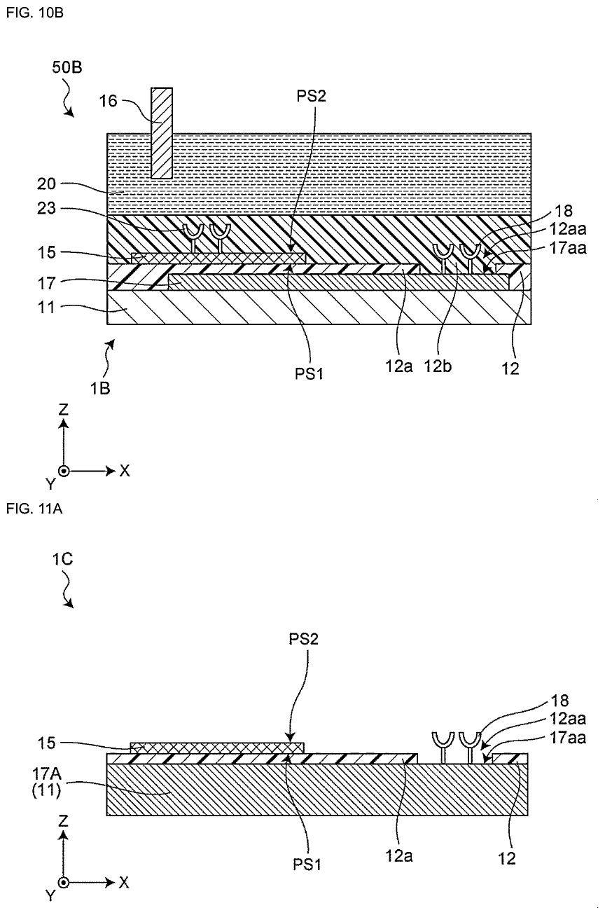

FIG. 9A to FIG. 9C schematically illustrate examples of the structure for the capacitive coupling. In the examples of the structure for the capacitive coupling, as illustrated in FIG. 9A, the third electrode 17, the insulating layer 12a, and an electrode layer 22 may be arranged in this order. The electrode layer 22 is made of, for example, a conductive material. For example, the electrode layer 22 may be the semiconductor sheet 15. The thickness T1 of the insulating layer 12a illustrated in FIG. 9A is equal or substantially equal to the thickness T1 of the insulating layer 12a illustrated in FIG. 4A.

In the examples of the structure for the capacitive coupling, as illustrated in FIG. 9B, the semiconductor sheet 15, the electric double layer 12b, and the electrolyte solution 20 may be arranged in this order. The thickness T2 of the electric double layer 12b illustrated in FIG. 9B is equal or substantially equal to the thickness T2 of the electric double layer 12b illustrated in FIG. 4B. For example, the structure illustrated in FIG. 9B is used for an example in which the capacitive coupling between the semiconductor sheet 15 and the electrolyte solution 20 occurs. In this case, the multiple attraction portions 18 may be disposed in or on the electric double layer 12b that is disposed on the semiconductor sheet 15.

In the examples of the structure for the capacitive coupling, as illustrated in FIG. 9C, the semiconductor sheet 15, the insulating layer 12a, the electric double layer 12b, and the electrolyte solution 20 are arranged in this order. The thickness T1 of the insulating layer 12a and the thickness T2 of the electric double layer 12b illustrated in FIG. 9C are equal to the thickness T1 of the insulating layer 12a illustrated in FIG. 4A and the thickness T2 of the electric double layer 12b illustrated in FIG. 4B. For example, the structure illustrated in FIG. 9C is used for an example in which the capacitive coupling between the semiconductor sheet 15 and the electrolyte solution 20 occurs. In this case, the multiple attraction portions 18 may be disposed in or on the electric double layer 12b that is disposed on the insulating layer 12a.

### Second Preferred Embodiment

A semiconductor sensor according to a second preferred embodiment of the present invention will be described.

According to the second preferred embodiment, differences from the first preferred embodiment will be mainly described. According to the second preferred embodiment, components the same or substantially the same as those according to the first preferred embodiment are designated by the same reference signs. According to the second preferred embodiment, the same or corresponding description as in the first preferred embodiment is omitted.

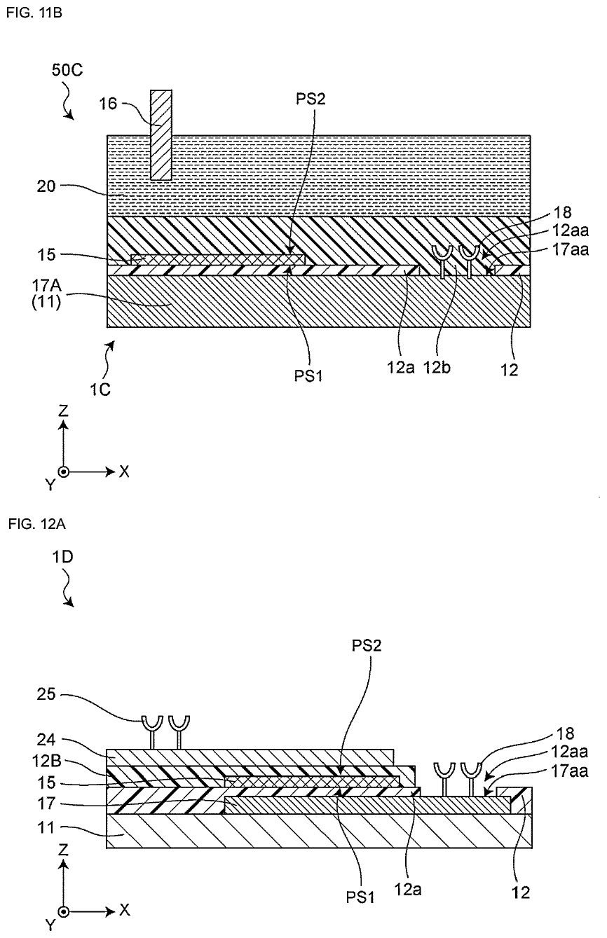

FIG. 10A schematically illustrates a sectional view of an example of a main structure of a semiconductor sensor 1B according to the second preferred embodiment of the present invention. FIG. 10B schematically illustrates a sectional view of an example of a main structure of a detection device 50B according to the second preferred embodiment of the present invention.

The second preferred embodiment differs from the first preferred embodiment in that multiple attraction portions 23 are disposed on the semiconductor sheet 15.

According to the second preferred embodiment, the multiple attraction portions 18 according to the first preferred embodiment are referred to as the multiple first attraction portions 18, and the multiple attraction portions 23 are referred to as the multiple second attraction portions 23.

As illustrated in FIG. 10A and FIG. 10B, the semiconductor sensor 1B includes the multiple second attraction portions 23 that are disposed on the semiconductor sheet 15 and that attract the object 2 to be detected. The multiple second attraction portions 23 are disposed on the second main surface PS2 of the semiconductor sheet 15. According to the second preferred embodiment, the multiple second attraction portions 23 have the same or substantially the same structure as the multiple first attraction portions 18.

As illustrated in FIG. 10B, the electric double layer 12b is provided on the dielectric layer 12 and the semiconductor sheet 15 with the semiconductor sensor 1B filled with the electrolyte solution 20 in the detection device 50B. The multiple second attraction portions 23 are covered by the electric double layer 12b.

### Advantageous Effects

The semiconductor sensor 1B according to the second preferred embodiment can obtain the following advantageous effects.

The semiconductor sensor 1B includes the multiple second attraction portions 23 that are disposed on the semiconductor sheet 15 and that attract the object 2 to be detected. With this structure, the performance of the semiconductor sensor 1B can be further improved. In the semiconductor sensor 1B, both surfaces of the semiconductor sheet 15 can be used. Specifically, in the semiconductor sensor 1B, gate modulation that is provided to the semiconductor sheet 15 due to the object 2 to be detected can be acquired from the first main surface PS1 and the second main surface PS2 of the semiconductor sheet 15. The object 2 to be detected can be attracted on an area increased from that according to the first preferred embodiment. This enables the sensor sensitivity to be improved.

In an example described according to the second preferred embodiment, the multiple second attraction portions 23 are the same or substantially the same as the multiple first attraction portions 18 but are not limited thereto. For example, the multiple second attraction portions 23 may differ from the multiple first attraction portions 18. In other words, the multiple second attraction portions 23 may detect an object to be detected different from that for the multiple first attraction portions 18.

### Third Preferred Embodiment

A semiconductor sensor according to a third preferred embodiment of the present invention will be described.

According to the third preferred embodiment, differences from the first preferred embodiment will be mainly described. According to the third preferred embodiment, components the same or substantially the same as those according to the first preferred embodiment are designated by like reference signs. According to the third preferred embodiment, the same or corresponding description as in the first preferred embodiment is omitted.

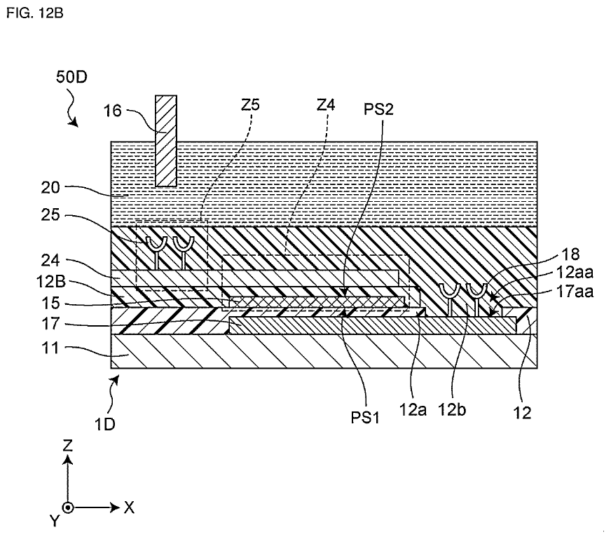

FIG. 11A schematically illustrates a sectional view of an example of a main structure of a semiconductor sensor 1C according to the third preferred embodiment of the present invention. FIG. 11B schematically illustrates a sectional view of an example of a main structure of a detection device 50C according to the third preferred embodiment of the present invention.

The third preferred embodiment differs from the first preferred embodiment in that a third electrode 17A defines and functions as the substrate 11.

As for the semiconductor sensor 1C, as illustrated in FIG. 11A and FIG. 11B, the third electrode 17A serves as the substrate 11. To define and function as the substrate 11 means that the third electrode 17A is integrally provided with the substrate 11 and has the function of the substrate 11.

The third electrode 17A is made of, for example, a highly doped Si substrate, an ITO substrate, or a Cu substrate.

### Advantageous Effects

The semiconductor sensor 1C according to the third preferred embodiment can obtain the following advantageous effects.

As for the semiconductor sensor 1C, the third electrode 17A defines and functions as the substrate 11. With this structure, the number of components that are included in the semiconductor sensor 1C can be decreased. In addition, the size of the semiconductor sensor 1C can be decreased.

### Fourth Preferred Embodiment

A semiconductor sensor according to a fourth preferred embodiment of the present invention will be described.

According to the fourth preferred embodiment, differences from the first preferred embodiment will be mainly described. According to the fourth preferred embodiment, components the same or substantially the same as those according to the first preferred embodiment are designated by like reference signs. According to the fourth preferred embodiment, the same or corresponding description as in the first preferred embodiment is omitted.

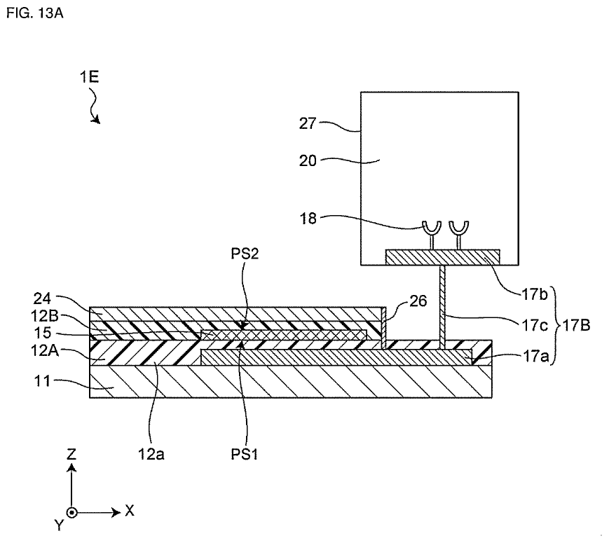

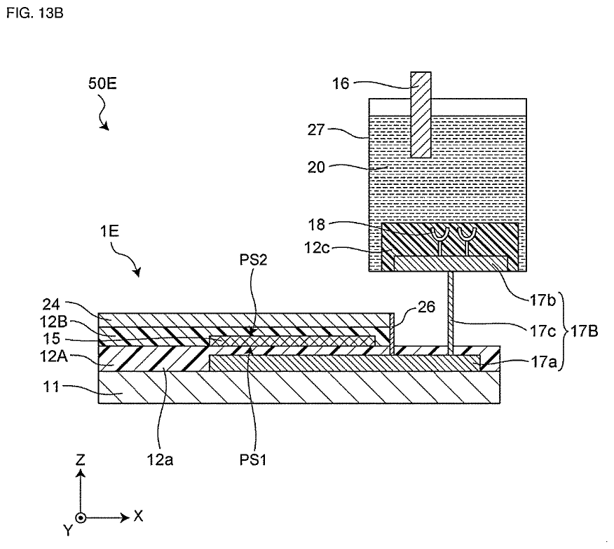

FIG. 12A schematically illustrates a sectional view of an example of a main structure of a semiconductor sensor 1D according to the fourth preferred embodiment of the present invention. FIG. 12B schematically illustrates a sectional view of an example of a main structure of a detection device 50D according to the fourth preferred embodiment of the present invention.

The fourth preferred embodiment differs from the first preferred embodiment in including a dielectric layer 12B, a fourth electrode 24 and multiple attraction portions 25.

According to the fourth preferred embodiment, the dielectric layer 12 that is disposed on the substrate 11 is referred to as the first dielectric layer 12. The dielectric layer 12B that is disposed on the insulating layer 12a of the first dielectric layer 12 is referred to as the second dielectric layer 12B. The multiple attraction portions 18 that are disposed on the surface 17aa of the third electrode 17 are referred to as the multiple first attraction portions 18. The multiple attraction portions 25 that are disposed in or on the fourth electrode 24 are referred to as the multiple third attraction portions 25. The additional electrode 16 is referred to as the fifth electrode 16.

As illustrated in FIG. 12A and FIG. 12B, the semiconductor sensor 1D includes the second dielectric layer 12B, the fourth electrode 24, and the multiple third attraction portions 25. The electric double layer 12b is provided on a surface of the fourth electrode 24 with the semiconductor sensor 1D filled with the electrolyte solution 20.

Second Dielectric Layer

The second dielectric layer 12B is disposed on the insulating layer 12a of the first dielectric layer 12 and covers the first electrode 13, the second electrode 14, and the semiconductor sheet 15. The second dielectric layer 12B is made of the same dielectric material as the first dielectric layer 12. According to the fourth preferred embodiment, the second dielectric layer 12B is defined by the insulating layer 12a.

Fourth Electrode

The fourth electrode 24 has a plate shape that includes a first end and a second end and that extends in the longitudinal direction. The fourth electrode 24 has a rectangular or substantially rectangular shape that extends in the X-direction in a plan view of the semiconductor sensor 1D. The fourth electrode 24 is made of the same conductive material as the third electrode 17.

The fourth electrode 24 is disposed on the second dielectric layer 12B. The fourth electrode 24 is disposed between the first electrode 13 and the second electrode 14 in a plan view of the semiconductor sensor 1D. Specifically, the first end of the fourth electrode 24 is disposed between the first electrode 13 and the second electrode 14. The fourth electrode 24 may partially overlap the first electrode 13 and the second electrode 14 in a plan view of the semiconductor sensor 1D. The direction in which the fourth electrode 24 extends is opposite the direction in which the third electrode 17 extends. In FIG. 12A and FIG. 12B, the fourth electrode 24 extends in the left-hand direction, and the third electrode 17 extends in the right-hand direction. The fourth electrode 24 overlaps the third electrode 17 in a region in which the semiconductor sheet 15 is disposed in a plan view of the semiconductor sensor 1D.

As illustrated in FIG. 12B, the electric double layer 12b is provided on the fourth electrode 24 with the electrolyte solution 20 filled. The electric double layer 12b is provided at the interface between the fourth electrode 24 and the electrolyte solution 20.

Multiple Third Attraction Portions

The multiple third attraction portions 25 are disposed on the fourth electrode 24 and attract the object 2 to be detected. According to the fourth preferred embodiment, the multiple third attraction portions 25 have the same or substantially the same structure as the multiple first attraction portions 18. The multiple third attraction portions 25 are covered by the electric double layer 12b.

In the semiconductor sensor 1D of the detection device 50D, capacitive coupling between the fourth electrode 24 and the semiconductor sheet 15 occurs at a portion Z4 illustrated in FIG. 12B. Capacitive coupling between the electrolyte solution 20 and the fourth electrode 24 occurs at a portion Z5 illustrated in FIG. 12B.

The fourth electrode 24 faces the semiconductor sheet 15 at the portion Z4 illustrated in FIG. 12B with the second dielectric layer 12B interposed therebetween. Specifically, the first end of the fourth electrode 24 faces the semiconductor sheet 15 with the second dielectric layer 12B interposed therebetween. In other words, a surface in contact with the second dielectric layer 12B at the first end of the fourth electrode 24 faces the second main surface PS2 of the semiconductor sheet 15 with the second dielectric layer 12B interposed therebetween. The thickness of the second dielectric layer 12B that is located between the fourth electrode 24 and the semiconductor sheet 15 is designed to be a thickness adjusted to such an extent that the capacitive coupling between the fourth electrode 24 and the semiconductor sheet 15 occurs. For example, the thickness of the second dielectric layer 12B is equal or substantially equal to that of the insulating layer 12a of the first dielectric layer 12. That is, in the case where the second dielectric layer 12B is defined by the insulating layer 12a, the thickness of the second dielectric layer 12B is equal to the thickness T1 of the insulating layer 12a illustrated in FIG. 4A.

The fourth electrode 24 faces the electrolyte solution 20 at the portion Z5 illustrated in FIG. 12B with the electric double layer 12b interposed therebetween. Specifically, the second end of the fourth electrode 24 faces the electrolyte solution 20 with the electric double layer 12b interposed therebetween. In other words, the surface at the second end of the fourth electrode 24 opposite the surface in contact with the second dielectric layer 12B faces the electrolyte solution 20 with the electric double layer 12b interposed therebetween. The thickness of the electric double layer 12b that is located between the fourth electrode 24 and the electrolyte solution 20 is designed to be a thickness adjusted to such an extent that the capacitive coupling between the fourth electrode 24 and the electrolyte solution 20 occurs. For example, the thickness of the electric double layer 12b is equal or substantially equal to the thickness T2 of the electric double layer 12b illustrated in FIG. 4B.

The capacitive coupling of the fourth electrode 24 with the electrolyte solution 20 and the semiconductor sheet 15 occurs, and the fourth electrode 24 consequently defines and functions as a top gate electrode in an electrically floating state.

### Advantageous Effects

The semiconductor sensor 1D according to the fourth preferred embodiment can obtain the following advantageous effects.

The semiconductor sensor 1D includes the second dielectric layer 12B, the fourth electrode 24, and the multiple third attraction portions 25. The second dielectric layer 12B is disposed on the first dielectric layer 12 and covers the first electrode 13, the second electrode 14, and the semiconductor sheet 15. The fourth electrode 24 is disposed on the second dielectric layer 12B. The multiple third attraction portions 25 are disposed on the fourth electrode 24 and attract the object 2 to be detected.

With this structure, the performance of the semiconductor sensor 1D can be further improved. As for the semiconductor sensor 1D, both surfaces of the semiconductor sheet 15 can be used. Specifically, the gate modulation that is provided to the semiconductor sheet 15 due to the object 2 to be detected can be acquired from the first main surface PS1 and the second main surface PS2 of the semiconductor sheet 15. The multiple third attraction portions 25 can attract the object 2 to be detected. The object 2 to be detected can be attracted on an area further increased from that according to the first preferred embodiment. This enables the sensor sensitivity of the semiconductor sensor 1D to be improved.

In an example described according to the fourth preferred embodiment, the second dielectric layer 12B is defined by the insulating layer 12a but is not limited thereto. The second dielectric layer 12B is made of a dielectric material. The thickness of the second dielectric layer 12B is designed such that the capacitive coupling can occur.

In an example described according to the fourth preferred embodiment, the multiple third attraction portions 25 are directly disposed on the fourth electrode 24 but are not limited thereto. The multiple attraction portions 25 are disposed in or on a portion at which the capacitive coupling between the fourth electrode 24 and the electrolyte solution 20 occurs. For example, a dielectric layer may be disposed on the surface of the fourth electrode 24, and the multiple third attraction portions 25 may be disposed on the fourth electrode 24 with the dielectric layer interposed therebetween.

In an example described according to the fourth preferred embodiment, the multiple third attraction portions 25 are the same or substantially the same as the multiple first attraction portions 18 but are not limited thereto. For example, the multiple third attraction portions 25 may differ from the multiple first attraction portions 18. In other words, the multiple third attraction portions 25 may detect an object to be detected different from that for the multiple first attraction portions 18.

### Fifth Preferred Embodiment

A semiconductor sensor according to a fifth preferred embodiment of the present invention will be described.

According to the fifth preferred embodiment, differences from the first preferred embodiment will be mainly described. According to the fifth preferred embodiment, components the same or substantially the same as those according to the first preferred embodiment are designated by like reference signs. According to the fifth preferred embodiment, the same or corresponding description as in the first preferred embodiment is omitted.

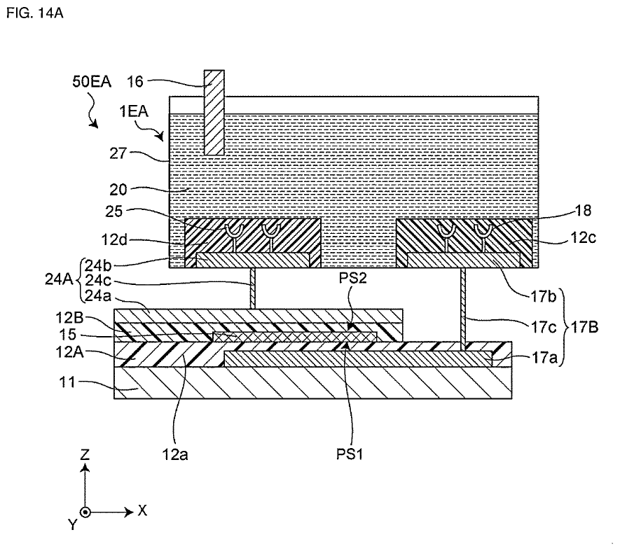

FIG. 13A schematically illustrates a sectional view of an example of a main structure of a semiconductor sensor 1E according to the fifth preferred embodiment of the present invention. FIG. 13B schematically illustrates a sectional view of an example of a main structure of a detection device 50E according to the fifth preferred embodiment of the present invention.

The fifth preferred embodiment differs from the first preferred embodiment in that the dielectric layer 12B, the fourth electrode 24, and a connection conductor 26 are included, a third electrode 17B includes a body electrode 17a, an outer electrode 17b, and a connection line 17c, the multiple attraction portions 18 are disposed on a surface of the outer electrode 17b, and the electrolyte solution 20 is stored in a container 27.

According to the fifth preferred embodiment, the dielectric layer 12A that is disposed on the substrate 11 is referred to as the first dielectric layer 12A. The dielectric layer 12B that is disposed on the first dielectric layer 12A is referred to as the second dielectric layer 12B. The additional electrode 16 is referred to as the fifth electrode 16.

For the third electrode 17B, the body electrode 17a is referred to as the first body electrode 17a in some cases. The outer electrode 17b is referred to as the first outer electrode 17b in some cases. The connection line 17c is referred to as the first connection line 17c in some cases.

As illustrated in FIG. 13A and FIG. 13B, the semiconductor sensor 1E includes the second dielectric layer 12B, the fourth electrode 24, the connection conductor 26, and the container 27. The detection device 50E includes the semiconductor sensor 1E, the fifth electrode 16, and the container 27.

The second dielectric layer 12B and the fourth electrode 24 are the same as those according to the fourth preferred embodiment, and the detailed description thereof is omitted.

Connection Conductor

The connection conductor 26 connects the third electrode 17B and the fourth electrode 24 to each other. The connection conductor 26 electrically connects the third electrode 17B and the fourth electrode 24 to each other. Specifically, the connection conductor 26 electrically connects the body electrode 17a of the third electrode 17B and the fourth electrode 24 to each other. The connection conductor 26 is made of, for example, a conductive material.

Container

The container 27 stores the electrolyte solution 20. The fifth electrode 16 is disposed in the container 27. The fifth electrode 16 is in contact with the electrolyte solution 20 that is stored in the container 27.

The third electrode 17B includes the body electrode 17a, the outer electrode 17b, and the connection line 17c.

Body Electrode

The body electrode 17a is disposed on the substrate 11 and is covered by the first dielectric layer 12A. The body electrode 17a has the same or substantially the same structure as the third electrode 17 according to the first preferred embodiment. The body electrode 17a faces the first main surface PS1 of the semiconductor sheet 15, and capacitive coupling between the body electrode 17a and the semiconductor sheet 15 occurs.

Outer Electrode

The outer electrode 17b is spaced apart from the body electrode 17a. According to the fifth preferred embodiment, the outer electrode 17b is disposed in the container 27 that stores the electrolyte solution 20. The outer electrode 17b has a plate shape. The outer electrode 17b is made of, for example, a conductive material as in the body electrode 17a.

As illustrated in FIG. 13B, an electric double layer 12c is provided on the surface of the outer electrode 17b with the container 27 filled with the electrolyte solution 20. According to the fifth preferred embodiment, the electric double layer 12c is the same or substantially the same as the electric double layer 12b according to the first preferred embodiment.

The outer electrode 17b is in contact with the electrolyte solution 20 with the electric double layer 12c interposed therebetween. Consequently, capacitive coupling between the outer electrode 17b and the electrolyte solution 20 occurs. The electric double layer 12c has a thickness adjusted to such an extent that the capacitive coupling between the outer electrode 17b and the electrolyte solution 20 occurs.

Connection Line

The connection line 17c connects the body electrode 17a and the outer electrode 17b to each other. The connection line 17c electrically connects the body electrode 17a and the outer electrode 17b to each other. The connection line 17c is made of, for example, a conductive material. The connection line 17c may be flexible.

The multiple attraction portions 18 are disposed on the surface of the outer electrode 17b. The multiple attraction portions 18 are disposed in or on a portion at which the capacitive coupling between the outer electrode 17b and the electrolyte solution 20 occurs. Specifically, the multiple attraction portions 18 are disposed on the surface of the outer electrode 17b and are covered by the electric double layer 12c. The multiple attraction portions 18 attract the object to be detected in the electrolyte solution 20 in the container 27.

### Advantageous Effects

The semiconductor sensor 1E according to the fifth preferred embodiment can obtain the following advantageous effects.

The semiconductor sensor 1E includes the second dielectric layer 12B, the fourth electrode 24, and the connection conductor 26. The second dielectric layer 12B is disposed on the first dielectric layer 12A and covers the first electrode 13, the second electrode 14, and the semiconductor sheet 15. The fourth electrode 24 is disposed on the second dielectric layer 12B. The connection conductor 26 connects the third electrode 17B and the fourth electrode 24 to each other. The third electrode 17B includes the body electrode 17a, the outer electrode 17b, and the connection line 17c. The body electrode 17a is covered by the first dielectric layer 12A. The outer electrode 17b is spaced apart from the first body electrode. The connection line 17c connects the body electrode 17a and the outer electrode 17b to each other. The multiple attraction portions 18 are disposed on the outer electrode 17b.

With this structure, the usability of the semiconductor sensor 1E can be improved. In addition, the number of components in contact with the electrolyte solution 20 can be decreased, and the semiconductor sensor 1E can be reduced or prevented from being degraded due to the electrolyte solution 20.

In an example described according to the fifth preferred embodiment, the detection device 50E includes the container 27 but is not limited thereto. The container 27 is not necessary. The semiconductor sensor 1E may include the container 27.

Third Modification

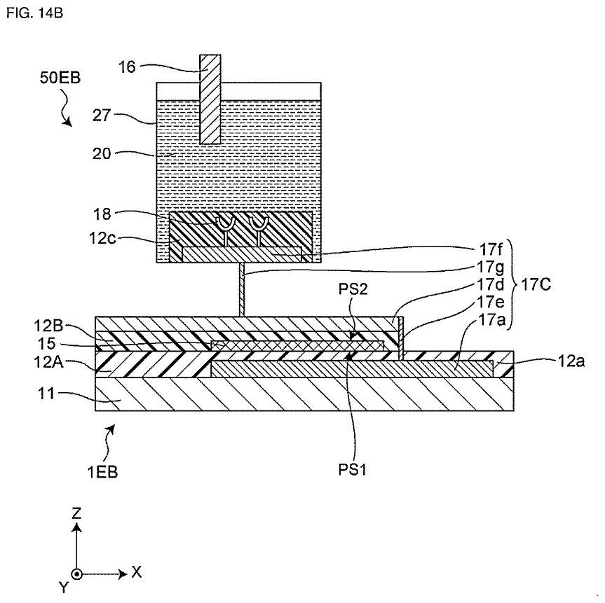

FIG. 14A schematically illustrates a sectional view of a main structure of a detection device 50EA according to a third modification to the fifth preferred embodiment of the present invention. As for a semiconductor sensor 1EA of the detection device 50EA, as illustrated in FIG. 14A, a fourth electrode 24A includes a body electrode 24a, an outer electrode 24b, and a connection line 24c. The multiple attraction portions 25 are disposed on a surface of the outer electrode 24b. An electric double layer 12d is provided on the surface of the outer electrode 24b with the electrolyte solution 20 filled.

According to the third modification, the body electrode 24a is referred to as the second body electrode 24a. The outer electrode 24b is referred to as the second outer electrode 24b. The connection line 24c is referred to as the second connection line 24c. The multiple attraction portions 25 are referred to as the multiple third attraction portions 25.

The second body electrode 24a is disposed on the second dielectric layer 12B. The second body electrode 24a has the same or substantially the same structure as the fourth electrode 24 according to the fifth preferred embodiment. The second body electrode 24a faces the second main surface PS2 of the semiconductor sheet 15, and capacitive coupling between the second body electrode 24a and the semiconductor sheet 15 occurs.

The second outer electrode 24b is spaced apart from the second body electrode 24a. The second outer electrode 24b is disposed in the container 27 and is in contact with the electrolyte solution 20. The second outer electrode 24b has the same or substantially the same structure as the first outer electrode 17b according to the fifth preferred embodiment.

The electric double layer 12d is provided on the surface of the second outer electrode 24b with the electrolyte solution 20 filled. According to the fifth preferred embodiment, the electric double layer 12d is the same or substantially the same as the electric double layer 12b according to the first preferred embodiment.

The second outer electrode 24b is in contact with the electrolyte solution 20 with the electric double layer 12d interposed therebetween. Consequently, capacitive coupling between the second outer electrode 24b and the electrolyte solution 20 occurs. The electric double layer 12d has a thickness adjusted to such an extent that the capacitive coupling between the second outer electrode 24b and the electrolyte solution 20 occurs.

The second connection line 24c connects the second body electrode 24a and the second outer electrode 24b to each other. The second connection line 24c electrically connects the second body electrode 24a and the second outer electrode 24b to each other. The second connection line 24c is made of, for example, a conductive material. The second connection line 24c may be flexible.

The multiple third attraction portions 25 are disposed on the surface of the second outer electrode 24b. The multiple third attraction portions 25 are disposed in or on a portion at which the capacitive coupling between the second outer electrode 24b and the electrolyte solution 20 occurs. Specifically, the multiple third attraction portions 25 are covered by the electric double layer 12d on the surface of the second outer electrode 24b. The multiple third attraction portions 25 attract the object 2 to be detected in the electrolyte solution 20 in the container 27. The multiple third attraction portions 25 have the same structure as the multiple first attraction portions 18.

Also, with this structure, the usability of the semiconductor sensor 1EA can be improved. The semiconductor sensor 1EA can be reduced or prevented from being degraded due to the electrolyte solution 20.

In addition, in the semiconductor sensor 1EA, both surfaces of the semiconductor sheet 15 can be used. The multiple third attraction portions 25 can attract the object to be detected. The object 2 to be detected can be attracted on an area further increased from that according to the first preferred embodiment. This enables the sensor sensitivity of the semiconductor sensor 1EA to be improved.

In an example described according to the third modification, the multiple third attraction portions 25 are the same or substantially the same as the multiple first attraction portions 18 but are not limited thereto. For example, the multiple third attraction portions 25 may differ from the multiple first attraction portions 18. In other words, the multiple third attraction portions 25 may detect an object to be detected different from that for the multiple first attraction portions 18.

In an example described according to the third modification, the multiple third attraction portions 25 are directly disposed on the second outer electrode 24b but are not limited thereto. The multiple third attraction portions 25 are disposed in or on a portion at which the capacitive coupling between the second outer electrode 24b and the electrolyte solution 20 occurs. For example, the second outer electrode 24b may be covered by a dielectric layer that includes, for example, an insulating layer, and the multiple third attraction portions 25 may be disposed in or on the dielectric layer on the second outer electrode 24b.

Fourth Modification

FIG. 14B schematically illustrates a sectional view of a main structure of a detection device according to a fourth modification to the fifth preferred embodiment of the present invention. As for a semiconductor sensor 1EB of a detection device 50EB, as illustrated in FIG. 14B, the third electrode 17C includes the body electrode 17a, a first outer electrode 17d, a first connection line 17e, a second outer electrode 17f, and a second connection line 17g.

The body electrode 17a is disposed on the substrate 11 and is covered by the first dielectric layer 12A. The body electrode 17a faces the first main surface PS1 of the semiconductor sheet 15, and capacitive coupling between the body electrode 17a and the semiconductor sheet 15 occurs.

The first outer electrode 17d is spaced apart from the body electrode 17a. The first outer electrode 17d is disposed on the second dielectric layer 12B. The first outer electrode 17d faces the semiconductor sheet 15 with the second dielectric layer 12B interposed therebetween. The first outer electrode 17d is disposed between the first electrode 13 and the second electrode 14 in a plan view of the semiconductor sensor 1EB. Specifically, a first end of the first outer electrode 17d is disposed between the first electrode 13 and the second electrode 14.

The first connection line 17e electrically connects the body electrode 17a and the first outer electrode 17d to each other. The first connection line 17e is made of, for example, a conductive material.

The second outer electrode 17f is spaced apart from the body electrode 17a. The second outer electrode 17f is disposed in the container 27. The second outer electrode 17f is in contact with the electrolyte solution 20 in the container 27. The multiple attraction portions 18 are disposed on a surface of the second outer electrode 17f.

In the case where the container 27 is filled with the electrolyte solution 20, the electric double layer 12c is provided between the second outer electrode 17f and the electrolyte solution 20. The multiple attraction portions 18 are covered by the electric double layer 12c.

The second connection line 17g electrically connects the first outer electrode 17d and the second outer electrode 17f to each other. The second connection line 17g is made of, for example, a conductive material.

Also, with this structure, the sensor sensitivity of the semiconductor sensor 1EB can be improved.

In an example described according to the fourth modification, a third electrode 17C includes the two outer electrodes 17d and 17f and the two connection lines 17e and 17g but is not limited thereto. The third electrode 17C includes the multiple outer electrodes and the multiple connection lines.

### Sixth Preferred Embodiment

A semiconductor sensor according to a sixth preferred embodiment of the present invention will be described.

According to the sixth preferred embodiment, differences from the second preferred embodiment will be mainly described. According to the sixth preferred embodiment, components the same or substantially the same as those according to the second preferred embodiment are designated by the same reference signs. According to the sixth preferred embodiment, the same or corresponding description as in the second preferred embodiment is omitted.

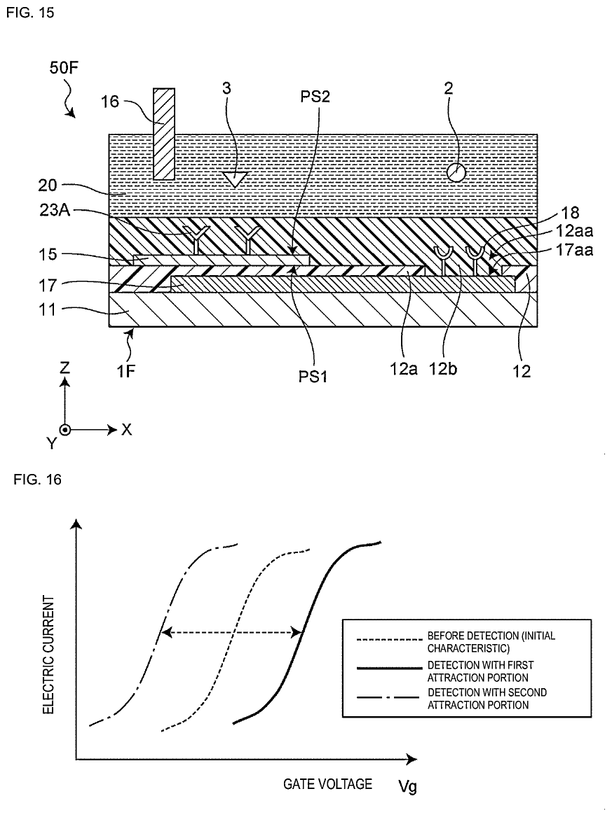

FIG. 15 schematically illustrates a sectional view of an example of a main structure of a detection device 50F according to the sixth preferred embodiment of the present invention.

The sixth preferred embodiment differs from the second preferred embodiment in that the multiple first attraction portions 18 and multiple second attraction portions 23A have different structures.

As illustrated in FIG. 15, the detection device 50F includes a semiconductor sensor 1F and the fifth electrode 16. In FIG. 15, the semiconductor sensor 1F is filled with the electrolyte solution 20. As for the semiconductor sensor 1F, the multiple second attraction portions 23A attract a second object 3 to be detected different from a first object 2 to be detected that the multiple first attraction portions 18 attract. For example, the multiple second attraction portions 23A include receptors that attract target molecules that differ from those for the multiple first attraction portions 18.

For example, the multiple first attraction portions 18 attract target molecules that have positive electric charge as the first object 2 to be detected. The multiple second attraction portions 23A attract target molecules that have negative electric charge.

FIG. 16 schematically illustrates an example of the variation in the electric current in the case where the multiple objects 2 and 3 to be detected are attracted. FIG. 16 illustrates examples of the changes in the electrical characteristics of the semiconductor sheet 15 in the case where the multiple first attraction portions 18 attract the target molecules that have the positive electric charge, and the multiple second attraction portions 23A attract the target molecules that have the negative electric charge.

As illustrated in FIG. 16, the detected target molecules can be identified based on the direction in which the electrical characteristics of the semiconductor sheet 15 change. In an example illustrated in FIG. 16, in the case where the first attraction portions 18 attract the target molecules that have the positive electric charge, the electrical characteristics of the semiconductor sheet 15 change in a positive direction from the initial characteristics before attraction. In the case where the second attraction portions 23A attract the target molecules that have the negative electric charge, the electrical characteristics of the semiconductor sheet 15 change in a negative direction from the initial characteristics before attraction.

A single semiconductor sensor element thus enables two kinds of target molecules to be detected.

The multiple second attraction portions 23A may include the multiple first attraction portions 18 and receptors that have different dynamic ranges (dissociation coefficients). The dynamic ranges mean the levels of the concentrations of detectable target molecules.

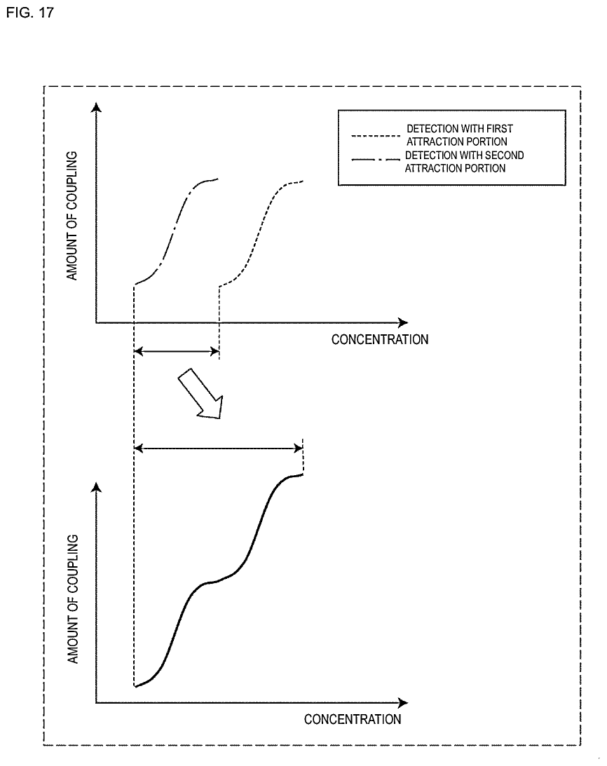

FIG. 17 schematically illustrates an example of the dynamic ranges. In FIG. 17, the first attraction portions 18 and the second attraction portions 23A use the receptors that have different dynamic ranges.

As illustrated in FIG. 17, the first attraction portions 18 and the second attraction portions 23A use the receptors that have the different dynamic ranges, and consequently, the dynamic ranges can be increased.

### Advantageous Effects

The semiconductor sensor 1F according to the sixth preferred embodiment can obtain the following advantageous effects.

As for the semiconductor sensor 1F, the multiple second attraction portions 23A attract the second object 3 to be detected different from the first object 2 to be detected that the multiple first attraction portions 18 attract. With this structure, the single semiconductor sensor element can measure the two kinds of the objects to be detected. In addition, the dynamic ranges can be increased.

Fifth Modification

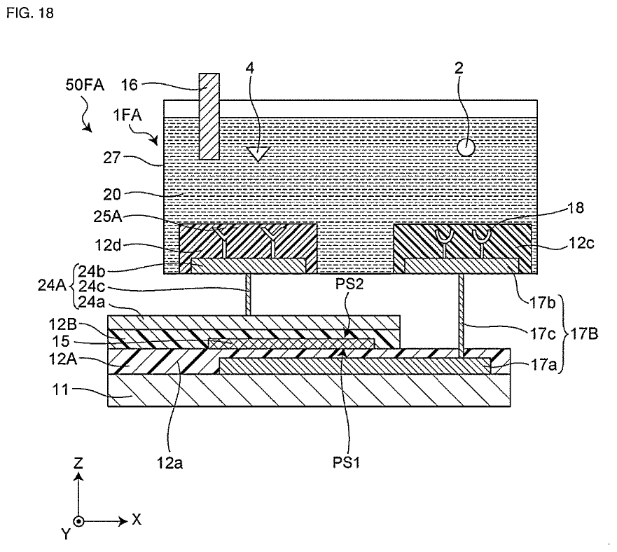

FIG. 18 schematically illustrates a sectional view of a main structure of a detection device 50FA according to a fifth modification to the sixth preferred embodiment of the present invention. As illustrated in FIG. 18, a semiconductor sensor 1FA of the detection device 50FA has the same or substantially the same structure as the semiconductor sensor 1EA according to the third modification to the fifth preferred embodiment except for multiple third attraction portions 25A. As for the semiconductor sensor 1FA, the multiple third attraction portions 25A attract a third object 4 to be detected different from the first object 2 to be detected that the multiple first attraction portions 18 attract. Also, with this structure, the same or substantially the same advantageous effects as those of the semiconductor sensor 1F can be exerted.

### Other Preferred Embodiments

According to another preferred embodiment, a semiconductor sensor may include the fourth electrode 24 according to the fourth or fifth preferred embodiment in addition to the structure according to the first preferred embodiment. As for the semiconductor sensor, a cover layer may be disposed on the fourth electrode 24.

Although the present invention is sufficiently described with reference to the accompanying drawings in relation to the preferred embodiments, various modifications and alterations may be made by a person skilled in the art. It should be understood that the modifications and alterations are included in the present invention recited by the accompanying claims without departing from the scope of the present invention.

### INDUSTRIAL APPLICABILITY

Semiconductor sensors according to preferred embodiments of the present invention are useful for, for example, a chemical sensor, a biosensor, a gas sensor, and a pH sensor.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A semiconductor sensor comprising:
a substrate;
a dielectric layer on the substrate;
a first electrode on the dielectric layer;
a second electrode spaced apart from the first electrode and on the dielectric layer;
a semiconductor sheet between the first electrode and the second electrode on the dielectric layer and electrically connecting the first electrode and the second electrode to each other;
a third electrode at least a portion of which is covered by the dielectric layer and faces the semiconductor sheet with the dielectric layer interposed therebetween; and
multiple first attraction portions at least on a surface of the third electrode or in or on the dielectric layer on the surface of the third electrode and attracting an object to be detected.

2. The semiconductor sensor according to claim 1, further comprising a cover layer on the dielectric layer and covering the first electrode, the second electrode, and the semiconductor sheet.

3. The semiconductor sensor according to claim 1, further comprising multiple second attraction portions on the semiconductor sheet and attracting an object to be detected.

4. The semiconductor sensor according to claim 3, wherein the multiple second attraction portions attract a second object to be detected different from a first object to be detected that the multiple first attraction portions attract.

5. The semiconductor sensor according to claim 1, wherein
the dielectric layer is a first dielectric layer covering at least a portion of the third electrode on the substrate; and
the semiconductor sensor further includes:
a second dielectric layer on the first dielectric layer and covering the first electrode, the second electrode, and the semiconductor sheet;
a fourth electrode on the second dielectric layer; and
multiple third attraction portions on the fourth electrode and attracting an object to be detected.

6. The semiconductor sensor according to claim 5, wherein
the fourth electrode includes:
a second body electrode on the second dielectric layer;
a second outer electrode spaced apart from the second body electrode; and
a second connection line connecting the second body electrode and the second outer electrode to each other; and
the multiple third attraction portions attracting the object to be detected are on a surface of the second outer electrode.

7. The semiconductor sensor according to claim 5, wherein the multiple third attraction portions attract a third object to be detected different from a first object to be detected that the multiple first attraction portions attract.

8. The semiconductor sensor according to claim 1, wherein
the dielectric layer is a first dielectric layer that covers at least a portion of the third electrode on the substrate;
the semiconductor sensor further includes:
a second dielectric layer on the first dielectric layer and covering the first electrode, the second electrode, and the semiconductor sheet;
a fourth electrode on the second dielectric layer; and
a connection conductor connecting the third electrode and the fourth electrode to each other;
the third electrode includes:
a first body electrode covered by the first dielectric layer;
a first outer electrode spaced apart from the first body electrode; and
a first connection line connecting the first body electrode and the first outer electrode to each other; and
the multiple first attraction portions are on a surface of the first outer electrode.

9. The semiconductor sensor according to claim 1, wherein the third electrode defines and functions as the substrate.

10. The semiconductor sensor according to claim 1, further comprising a calculator to receive an electrical signal outputted from the semiconductor sheet and to calculate an amount of the object to be detected, based on the electrical signal.

11. A detection device comprising:
the semiconductor sensor according to claim 1; and
a fifth electrode to control an electric current between the first electrode and the second electrode.

12. The detection device according to claim 11, further comprising a cover layer on the dielectric layer and covering the first electrode, the second electrode, and the semiconductor sheet.

13. The detection device according to claim 11, further comprising multiple second attraction portions on the semiconductor sheet and attracting an object to be detected.

14. The detection device according to claim 13, wherein the multiple second attraction portions attract a second object to be detected different from a first object to be detected that the multiple first attraction portions attract.

15. The detection device according to claim 11, wherein
the dielectric layer is a first dielectric layer covering at least a portion of the third electrode on the substrate; and
the semiconductor sensor further includes:
a second dielectric layer on the first dielectric layer and covering the first electrode, the second electrode, and the semiconductor sheet;
a fourth electrode on the second dielectric layer; and
multiple third attraction portions on the fourth electrode and attracting an object to be detected.

16. The detection device according to claim 15, wherein
the fourth electrode includes:
a second body electrode on the second dielectric layer;
a second outer electrode spaced apart from the second body electrode; and
a second connection line connecting the second body electrode and the second outer electrode to each other; and
the multiple third attraction portions attracting the object to be detected are on a surface of the second outer electrode.

17. The detection device according to claim 15, wherein the multiple third attraction portions attract a third object to be detected different from a first object to be detected that the multiple first attraction portions attract.

18. The detection device according to claim 11, wherein
the dielectric layer is a first dielectric layer that covers at least a portion of the third electrode on the substrate;
the semiconductor sensor further includes:
a second dielectric layer on the first dielectric layer and covering the first electrode, the second electrode, and the semiconductor sheet;
a fourth electrode on the second dielectric layer; and
a connection conductor connecting the third electrode and the fourth electrode to each other;
the third electrode includes:
a first body electrode covered by the first dielectric layer;
a first outer electrode spaced apart from the first body electrode; and
a first connection line connecting the first body electrode and the first outer electrode to each other; and
the multiple first attraction portions are on a surface of the first outer electrode.

19. The detection device according to claim 11, wherein the third electrode defines and functions as the substrate.

20. The detection device according to claim 11, further comprising a calculator to receive an electrical signal outputted from the semiconductor sheet and to calculate an amount of the object to be detected, based on the electrical signal.
